(19) United States
(12) Patent Application Publication
(10) Pub. No.: US 2023/0395553 A1
(43) Pub. Date: Dec. 7, 2023

(54) PACKAGE DEVICE PREVENTING SOLDER OVERFLOW

(71) Applicant: PANJIT INTERNATIONAL INC., Kaohshiung City (TW)

(72) Inventors: CHUNG-HSIUNG HO, KAOHSIUNG CITY (TW); SHUN-CHI SHEN, KAOHSIUNG CITY (TW); CHI-HSUEH LI, TAINAN CITY (TW)

(21) Appl. No.: 17/853,100

(22) Filed: Jun. 29, 2022

(30) Foreign Application Priority Data
Jun. 2, 2022 (TW) 111120721

(51) Int. Cl. H01L 23/00; H01L 23/495

(52) U.S. Cl. CPC H01L 24/32; H01L 24/33; H01L 24/40; H01L 24/73; H01L 23/49537; H01L 24/77; H01L 2924/3841; H01L 24/16; H01L 24/81; H01L 24/83; H01L 2224/81815; H01L 2224/83815; H01L 2224/16245; H01L 2224/73213; H01L 2224/73205; H01L 2224/73263; H01L 2224/73253; H01L 2224/77745; H01L 2224/3303; H01L 2224/33055; H01L 2224/33181; H01L 2224/4007; H01L 2224/40245; H01L 2224/3201; H01L 2224/32055; H01L 2224/32054; H01L 2224/32059; H01L 2224/26145

(57) ABSTRACT

A package device preventing solder overflow provides a space or structure to limit the location of the solder when dispensing the solder. The package device includes a die, an anti-overflow layer, a first pin, a second pin, and a package body. The die has an electrode pad. The anti-overflow layer is disposed on a top surface of the electrode pad and has an opening to expose the top surface of the electrode pad. The first pin is connected to the die. The second pin is soldered to the electrode pad of the die through the opening of the anti-overflow layer. The package body covers the die.

### CROSS REFERENCE TO RELATED APPLICATIONS

The present application claims priority to Taiwan application No. 111120721, filed on Jun. 2, 2022, the content of which is hereby incorporated by reference in its entirety.

### BACKGROUND OF THE INVENTION

### 1. Field of the Invention

The present invention relates to a package device, and in particular to a package device preventing solder overflow.

### 2. Description of Related Art

Referring to FIG. 4A to FIG. 4L, a conventional semiconductor device packaging method is shown. Referring to 4A and FIG. 4B, a wafer 60 is prepared. Multiple die units 61 are formed in the wafer 60. A top surface of each die unit 61A has an electrode pad 62. Referring to FIG. 4C, the wafer 60 is cut to separate the die units 61 from each other, and each die unit 61 forms an individual single die 63. The die 63 includes a body 630 and the electrode pad 62 disposed on the top surface of the body 630.

Referring to FIGS. 4D to 4F, a first lead frame 64 is prepared. The first lead frame 64 includes multiple first pins 640. The dies 63 are respectively disposed on the solder layers 641 on the first pins 640, wherein the bottom of each die 63 is disposed on each of the solder layers 641, and the surface of the electrode pad 62 of the die 63 faces upward.

Referring to FIG. 4G, for dispensing, a solder 65 is dispensed on the surface of the electrode pad 62 of each die 63 by a dispensing machine.

Then, second pins are soldered. The second pins are disposed on a second lead frame (not shown in the figure). That is, two opposite sides of the second lead frame extend respectively to form the second pins like a fish skeleton shape. And the positions of the second pins correspond to the positions of the dies 63 shown in FIG. 4E and FIG. 4F respectively. Therefore, when the second lead frame is disposed on the first lead frame 64, the second pins can be respectively connected to the dies 63. Referring to FIG. 4H and FIG. 4I, the bottom surface of the end of the second pin 66 has a protruding portion 660 protruding downward. The protruding portion 660 is butted with the solder 65 from above the die 63, and then a reflow process is performed to solder the protruding portion 660 of the second pin 66 to the electrode pad 62 of the die 63, and to solder the bottom of the die 63 to the first pins 640. During the reflow process, the solder 65 melts into liquid, and can be attached to the surface of the electrode pad 62 and the protruding portion 660 of the second pins 66 at the same time. After the solder 65 is cooled and solidified, it can be fixed and electrically connected to the electrode pad 62 and the second pins 66.

Referring to FIG. 4J, a molding step is performed to form a package body 67. The package body 67 covers the die 63. Finally, the package body 67 is removed from the first lead frame 64 to obtain a package product 68 as shown in FIG. 4K.

In the dispensing step of FIG. 4G, limited by the precision of the dispensing machine and the characteristics of the solder, the amount of solder 65 distributed to the electrode pad 62 of the die 63 is not uniform, and the position of the solder 65 may also be deviated. For example, when the solder 65 of the die 63 is distributed more widely, as shown in FIG. 4L, it may cause the solder 65A to overflow to the area other than the electrode pad 62. Since the solder 65 is electrically conductive, the overflowing solder 65A may cause abnormality of short circuit of the dies 63A or other electrical abnormality.

### SUMMARY OF THE INVENTION

In view of the above problems, the present invention provides a package device preventing solder overflow, so as to overcome the problem of solder overflow described in the prior art.

A package device preventing solder overflow comprises:
a die with an electrode pad;
an anti-overflow layer disposed on a top surface of the electrode pad and having an opening to expose the surface of the electrode pad;
a first pin connected to the die;
a second pin soldered to the electrode pad of the die through the opening of the anti-overflow layer; and
a package body covering the die.

According to the package device, the second pin is soldered to the electrode pad of the die through the opening of the anti-overflow layer. That is, solder is provided in the opening of the anti-overflow layer for soldering. Because the anti-overflow layer has a thickness and the solder itself has cohesive force, the position of the solder is restricted by the anti-overflow layer to prevent the solder from overflowing.

A package device preventing solder overflow, comprises:
a die with an electrode pad;
a first pin connected to the die;
a second pin opposite to the first pin at an interval;
a bridge component including:
   a first end having a concave portion, wherein the concave portion is soldered to the electrode pad of the die; and
   a second end connected to the second pin; and
a package body covering the die.

According to the package device, the concave portion of the bridge component is soldered to the electrode pad of the die, that is, the concave portion of the bridge component restricts the position of the solder to effectively prevent the solder from overflowing.

Based on the above, when the solder is dispensed on the surface of the electrode pad, the present invention provides a space or structure that can limit the position of the solder, which can effectively prevent the solder from overflowing during the soldering process.

### BRIEF DESCRIPTION OF THE DRAWINGS

FIGS. 1A to 1M are schematic diagrams of a manufacturing process of a first embodiment of the present invention;

FIGS. 2A to 2J are schematic diagrams of a manufacturing process of a second embodiment of the present invention;

FIGS. 3A to 3F, FIG. 3I and FIG. 3J are schematic diagrams of the manufacturing process of the third embodiment of the present invention;

FIG. 3G is a schematic perspective view of a suction nozzle used in a third embodiment of the present invention;

FIG. 3H is a schematic cross-sectional view of the suction nozzle used in the third embodiment of the present invention; and

FIG. 4A to FIG. 4L are schematic diagrams of a manufacturing process of a conventional package device.

### DETAILED DESCRIPTION OF THE PREFERRED EMBODIMENTS

During packaging process, solder is dispensed onto a surface of an electrode pad of a die (or bare die), so that the die can be soldered to a lead frame or other metal components. Wherein, the distribution state of the solder is closely related to the soldering quality. In order to prevent the solder from overflowing and optimize the soldering quality, the technical feature of the present invention is to provide a space or structure that can limit the position of the solder when distributing the solder. It should be noted that, the present invention is preferably applied to the die structure that needs to be soldered on its top surface. The die can be, for example, a die of a diode, a triode, or a metal oxide semi-field effect transistor (MOS FET), but is not limited thereto. The present invention is detailed below.

### 1. First Embodiment

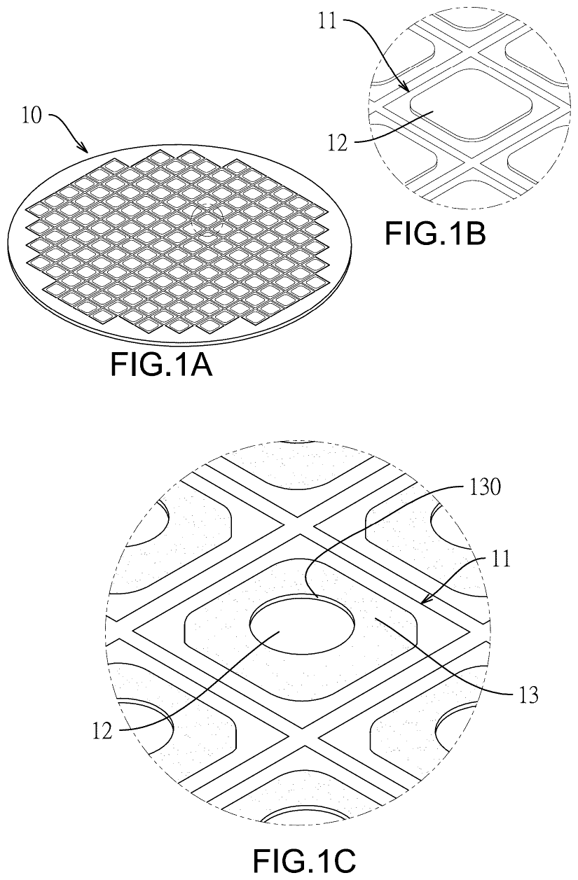

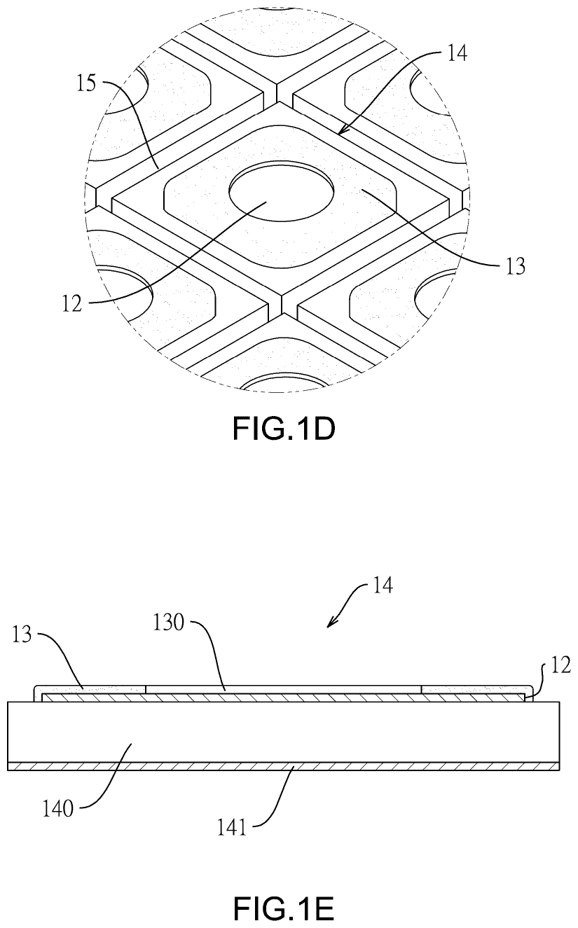

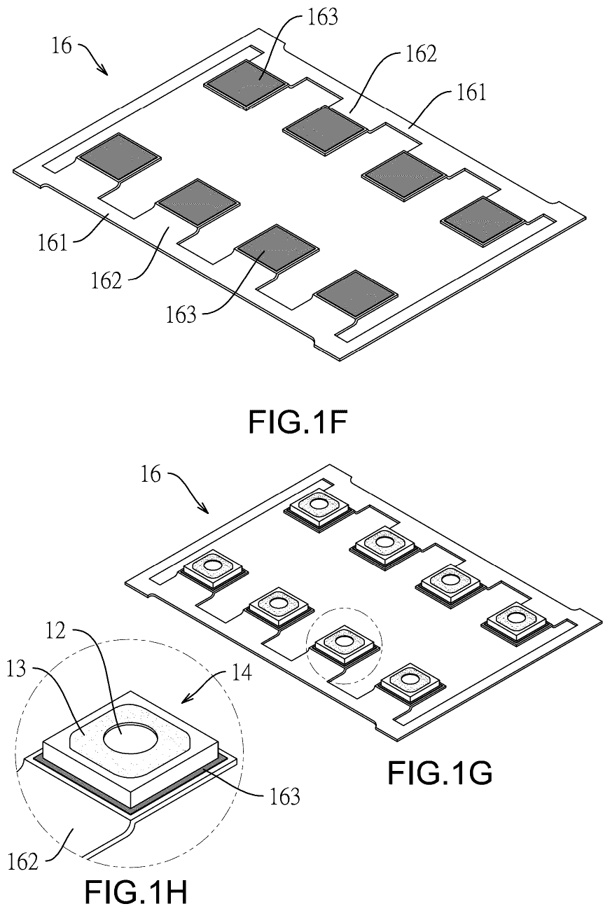

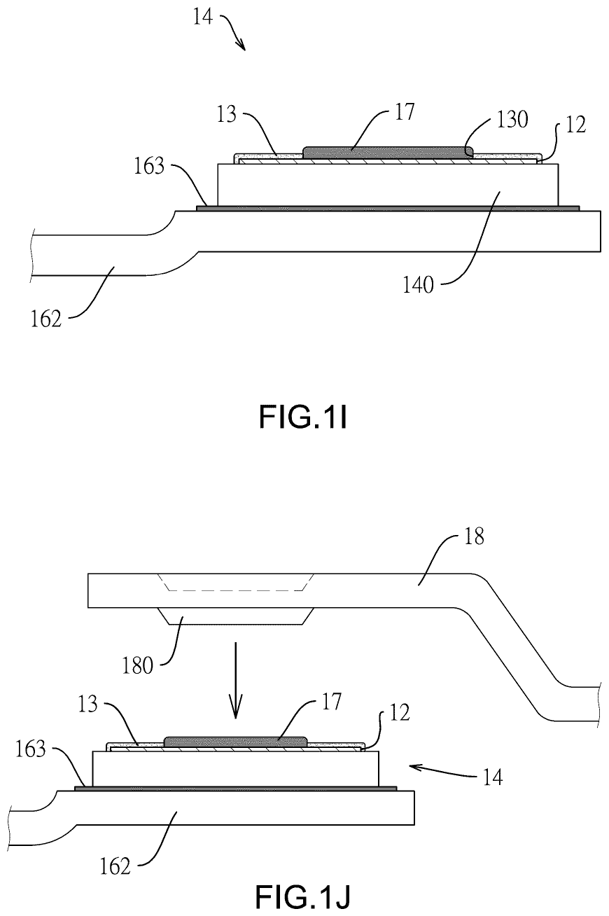

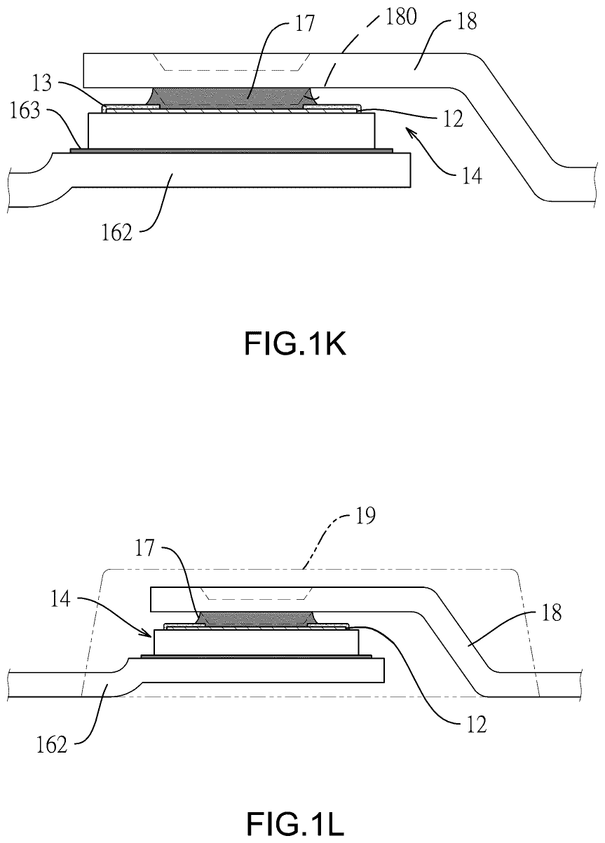

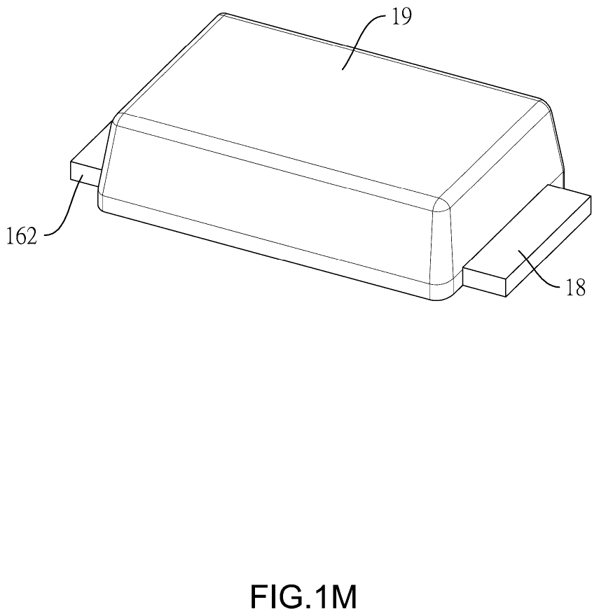

Referring to FIG. 1A and FIG. 1B, a wafer 10 is prepared. Multiple die units 11 are formed in the wafer 10. An electrode pad 12 is formed on a top surface of each die unit 11.

Referring to FIG. 1C, an anti-overflow layer 13 is disposed on the electrode pad 12 of each die unit 11, and the center of the anti-overflow layer 13 has an opening 130. That is, the anti-overflow layer 13 partially covers the electrode pad 12, and the surface of the electrode pad 12 is exposed to the opening 130. On the other hand, the size of the electrode pad 12 may be smaller than the size of the anti-overflow layer 13, and the edge of the electrode pad 12 is within the edge of the anti-overflow layer 13. For example, the anti-overflow layer 13 can be manufactured by a photolithography process, and the photolithography process includes: coating a PI (Polyimide) layer on the surface of the wafer 10; then coating a photoresist layer on the PI layer; and then removing the photoresist layer after patterning the photoresist layer and the PI layer, wherein the remaining part of the PI layer forms the structure of the anti-overflow layers 13.

In addition to the photolithography process, the anti-overflow layer 13 can also be manufactured by a laser forming process, a printing process, or other methods. For example, in the laser forming process, a PI layer can be coated on the surface of the wafer 10 at first. After ablating a specific position of the PI layer by laser for patterning, part of the PI layer can be removed, and the remaining part of the PI layer forms the structure of the anti-overflow layers 13. In the printing process, the size and position of the holes on the screen-printing plate correspond to the structure of the anti-overflow layers 13. Therefore, the PI material can be directly printed on the surface of the wafer 10 through the screen-printing plate to form the anti-overflow layers 13.

The wafer 10 is then cut to separate the die units 11 from each other. Referring to FIG. 1D, each die unit 110 forms a single die 14, and there are cutting channels 15 formed after cutting between adjacent dies 14. FIG. 1E is a schematic cross-sectional view of an individual die 14, which includes a body 140, the electrode pad 12 disposed on the top surface of the body 140, and the anti-overflow layer 13 disposed on the electrode pad 12. The center of the anti-overflow layer 13 has the opening 130, and the surface of the electrode pad 12 is exposed to the opening 130. A bottom contact 141 can also be formed on the bottom surface of the body 140, but is not limited to this.

Referring to FIG. 1F, a first lead frame 16 is prepared. The first lead frame 16 is a hollow frame and includes two side bars 161. The two side bars 161 are disposed opposite to each other, and respectively extend inward to form multiple first pins 162 disposed at intervals. Each of the first pins 162 is a plate body, and a solder layer 163 is distributed on the top surface thereof. It should be noted that, the structure of the first lead frame 16 is only for illustration. The solder layers 163 may be solder paste coated on the first pins 162 by screen printing.

Referring to FIG. 1G and FIG. 1H, a die bond is performed to respectively place the dies 14 on the solder layers 163 of the first pins 162, wherein the bottom contact 141 on the bottom surface of the die 14 is disposed on the solder layer 163. The top surface of the die 14 faces upward, that is, the surface of the electrode pad 12 faces upward.

Referring to FIG. 1I, for dispensing, a solder 17 can be distributed on the electrode pad 12 of each die 14 by a dispensing machine, and the solder 17 is located in the opening 130 of the anti-overflow layer 13. Because the anti-overflow layer 13 has a thickness and the solder 17 has cohesive force, the position of the solder 17 is limited within the opening 130 of the anti-overflow layer 13, wherein the solder 17 may be solder paste.

On the other hand, the arrangement of the solder 17 is not limited to the aforementioned dispensing method. For example, the dies 14 may be separated from each other after the step of cutting the wafer 10 shown in FIG. 1D. However, the relative positions between the dies 14 remain fixed, the solders 17 can be directly printed and coated in the openings 130 of the anti-overflow layer 13 on the dies 14 by screen printing. It can be known that the sizes and positions of the multiple holes on the screen-printing plate correspond to the sizes and positions of the openings 130 of the anti-overflow layers 13.

Referring to FIG. 1J and FIG. 1K, the second pins 18 are soldered. Multiple second pins 18 are disposed on a second lead frame (not shown in the figure), that is, two opposite sides of the second lead frame extend respectively to form the second pins 18 like a fish skeleton shape. The positions of the second pins 18 correspond to the positions of the dies 14 shown in FIG. 1G and FIG. 1H respectively. Therefore, when the second lead frame is disposed on the first lead frame 16, the second pins 18 can be respectively connected to the dies 14. Referring to 1J and FIG. 1K, the bottom surface of one end of each of the second pins 18 has a protruding portion 180 protruding downward. The protruding portion 180 is connected to the solder 17 from above the die 14, and then a reflow process is preformed to solder the protruding portion 180 of the second pin 18 to the electrode pad 12 of the die 14, and to solder the bottom contact 141 (as shown in FIG. 1E) at the bottom of the die 14 to the first pin 162.

Referring to FIG. 1L, a molding step is performed to form a package body 19. The package body 19 completely covers the die 14 and partially covers the first pin 162 and the second pin 18. That is, one end of the first pin 162 opposite to the die 14 is exposed to the package body 19, and one end of the second pin 18 opposite to the die 14 is exposed to the package body 19.

Then, the first lead frame 16 and the second lead frame are cut to obtain a package product of the present invention as shown in FIG. 1M.

Therefore, the embodiment of the package device of the present invention includes a die 14, an anti-overflow layer 13, a first pin 162, and a second pin 18. The die 14 includes a body 140 and an electrode pad 12. The electrode pad 12 can be disposed on the top surface of the body 140. The die 14 can also include a bottom contact 141 disposed on the bottom surface of the body 140. But the structure of the die 14 is not limited thereto. The anti-overflow layer 13 is disposed on the top surface of the electrode pad 12. The anti-overflow layer 13 has an opening 130, and the surface of the electrode pad 12 is exposed to the opening 130. The inner end of the first pin 162 is connected to the die 14, for example, soldered to the bottom contact 141 at the bottom of the die 14. The inner end of the second pin 18 is soldered to the electrode pad 12 of the die 14 through the opening 130 of the anti-overflow layer 13. That is, there is a solder layer 163 cured by reflow between the inner end of the first pin 162 and the bottom contact 141 of the die 14. There is solder 17 cured by reflow between the inner end of the second pin 18 and the electrode pad 12 and within the opening 130 of the anti-overflow layer 13. The package body 19 covers the die 14, the inner end of the first pin 162, and the inner end of the second pin 18. The outer end of the first pin 162 and the outer end of the second pin 18 may be exposed or extended out of the package body 19.

In the first embodiment of the present invention, the anti-overflow layer 13 is used to limit the position of the solder 17. Wherein, as the anti-overflow layer 13 has a thickness, the anti-overflow layer 13 can block the flow of the solder 17 on the wall surface of the opening 130. And the solder 17 itself also has cohesive force, so the position of the solder 17 is naturally restricted to the opening 130 of the anti-overflow layer 13 and does not overflow outward.

### 2. Second Embodiment

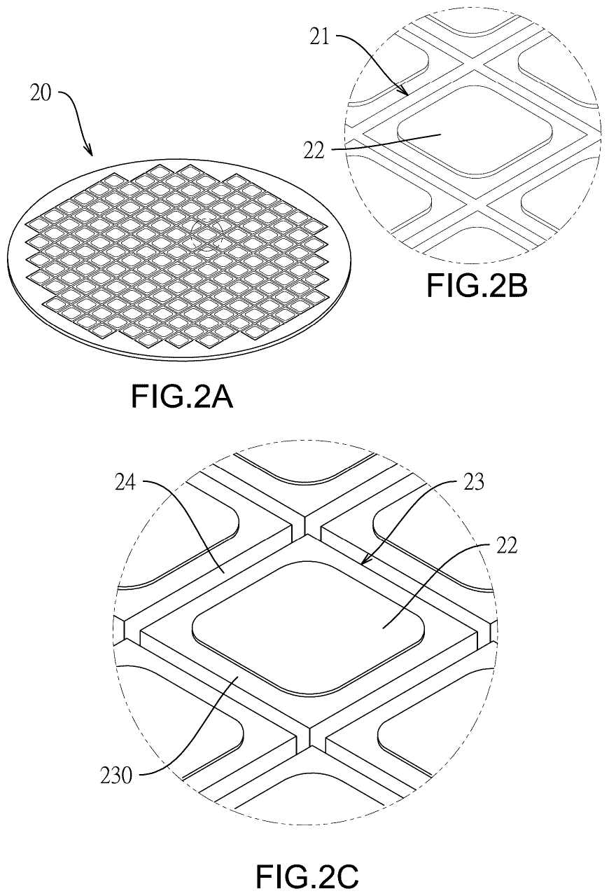

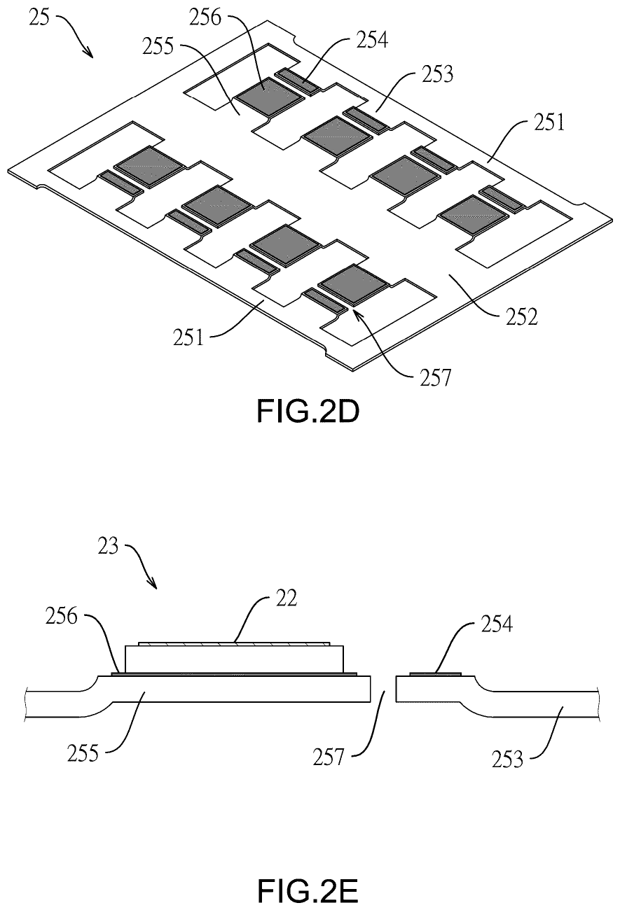

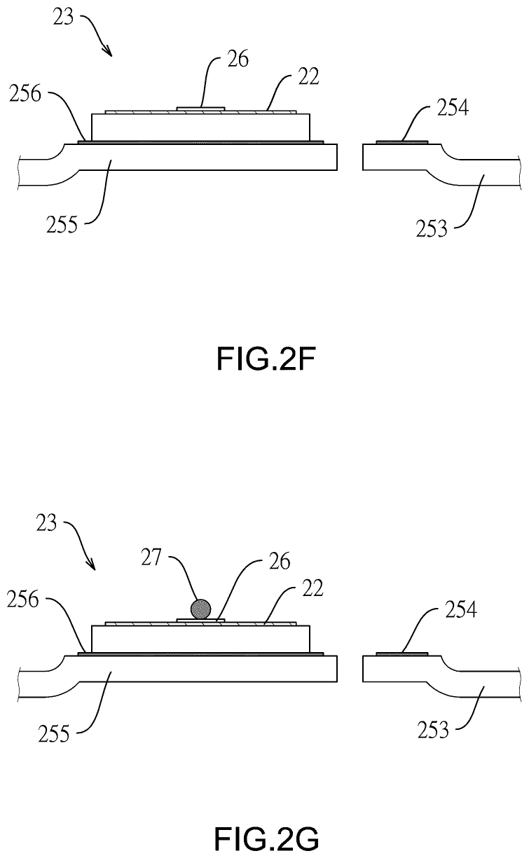

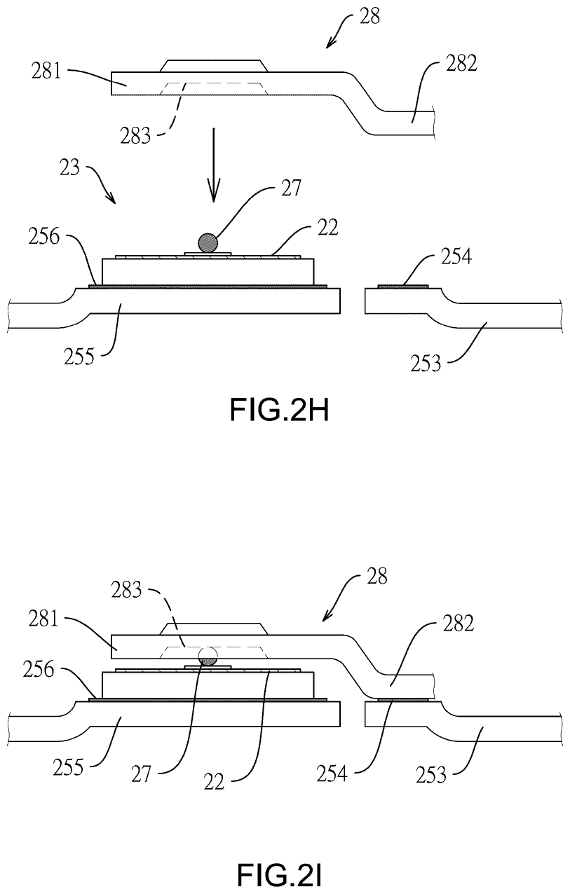

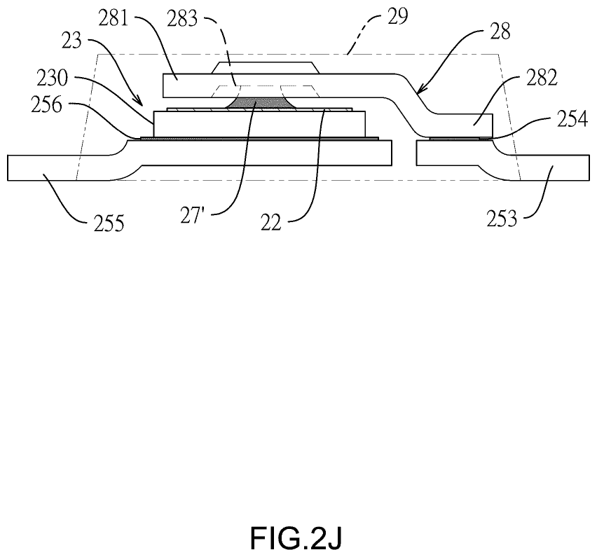

Referring to FIG. 2A and FIG. 2B, a wafer 20 is prepared. Multiple die units 21 are formed in the wafer 20. An electrode pad 22 is formed on a top surface of each die unit 21.

After cutting the wafer 20, the die units 21 are separated from each other. Referring to FIG. 2C, each die unit 21 forms a single die 23. There are cutting channels 24 formed after cutting between adjacent dies 23. The die 23 includes a body 230 and the electrode pad 22 disposed on the top surface of the body 230. The bottom surface of the body 230 can also form a bottom contact (by referring to the bottom contact 141 shown in FIG. 1E), but the present invention is not limited to this.

Referring to 2D, a first lead frame 25 is prepared, and the first lead frame 25 includes two side bars 251 and a backbone 252 located between the side bars 251 and parallel to each other. The backbone 252 is like a fish skeleton shape, and two opposite sides of the backbone 252 extend outward to form multiple first pins 255 disposed at intervals. Each of the first pins 255 is a plate body, and a solder layer 256 is provided on the top surface thereof. The two side bars 251 are disposed opposite to each other, and respectively extend inward to form multiple second pins 253 disposed at intervals. Each of the second pins 253 is a plate body, and a solder layer 254 is provided on the top surface thereof. The positions of the first pins 255 correspond to the positions of the second pins 253 respectively, and there is a gap 257 between the ends of the two adjacent second pins 253 and the first pins 255. That is to say, each of the first pins 255 is provided with each of the second pins 253 opposite to each other at an interval. It should be noted that, the structure of the first lead frame 25 is for illustration only, but not limit to this. The solder layers 256, 254 may be solder pastes coated on the first pins 255 and the second pins 253 by screen printing, respectively.

Referring to FIG. 2E, die bonding is performed to place the dies 23 on the solder layer 256 of the first pins 255. Wherein, the top surface of the die 23 faces upward, that is, the surface of the electrode pad 22 faces upward.

Then, a solder is placed on the surface of the electrode pads 22 of the dies 23. Wherein, the soldering can be performed by ball bonding. Regarding the ball bonding, please refer to FIG. 2F. Firstly, the flux 26 can be distributed. The flux 26 can be distributed on the center of the surface of the electrode pads 22 of the die 23 by a glue dispenser. Referring to FIG. 2G, for each die 23, at least one solder ball 27 is disposed on the flux 26, and the at least one solder ball 27 is the above-mentioned solder, such as a solder ball. In this embodiment, for each die 23, only one solder ball 27 is used as an example for description. In practical application, multiple solder balls 27 may be provided according to the needs of soldering. On the other hand, the ball bonding of FIG. 2F and FIG. 2G can be replaced by a screen printing, and the solder is directly printed and coated on the surface of the electrode pads 22 of the dies 23. It can be known that the positions of the multiple holes on the screen-printing plate correspond to the positions of the electrode pads 22 of the dies 23.

Referring to FIGS. 2H and 2I, the bridge components 28 are soldered. Wherein, multiple bridge components 28 are disposed on a second lead frame (not shown in the figure). That is to say, the bridge components 28 are formed by extending the opposite sides of the second lead frame respectively to be like a fish skeleton shape. And the positions of the bridge components 28 correspond to the positions of the solder layers 254 shown in FIG. 2D and the positions of the electrode pads 22 shown in 2E. Therefore, when the second lead frame is disposed on the first lead frame 25, the bridge component 28 can respectively connect the dies 14 to the second pins 253. As shown in FIGS. 2H and 2I, each of the bridge components 28 includes a first end 281 and a second end 282. The bottom surface of the first end 281 has a concave portion 283. The concave portion 283 moves from above the die 23 to the solder ball 27 to be butted, so that the solder ball 27 enters the space of the concave portion 283. And the solder ball 27 can abut on the bridge component 28 in the concave portion 283. The second end 282 of the bridge component 28 is disposed on the solder layer 254 of the second pin 253. Then a reflow process is performed to solder the concave portion 283 of the bridge component 28 to the electrode pad 22 of the die 23, to solder the bottom of the die 23 to the first pin 255, and to solder the second end 281 of the bridge component 28 to the second pin 253.

Referring to FIG. 2J, molding is performed to form a package body 29. The package body 29 completely covers the die 23 and the bridge component 28, and partially covers the first pin 255 and the second pin 253. That is, one end of the first pin 255 opposite to the die 23 is exposed to the package body 29, and one end of the second pin 253 opposite to the die 23 is exposed to the package body 29. Then, the first lead frame 25 and the second lead frame are cut to remove the package body 29 to obtain a product of the package device of the present invention (its appearance may be referred to FIG. 1M).

Therefore, referring to FIG. 2J, the second embodiment of the package device of the present invention includes a die 23, a first pin 255, a second pin 253, and a bridge component 28. The die 23 includes a body 230 and an electrode pad 22. The electrode pad 22 is disposed on the top surface of the body 230. The die 23 can also include a bottom contact (by referring to the bottom contact 141 shown in FIG. 1E), and the bottom contact can be provided on the bottom surface of the body 230, but the structure of the die 23 is not limited to this. The first pin 255 is connected to the die 23. For example, the inner end of the first pin 255 can be soldered to the bottom contact of the die 23. The second pin 253 is disposed on the first pin 255 at an interval. The bridge component 28 has the electrical conductivity. The first end 281 of the bridge component 28 is soldered to the electrode pad 22 of the die 23. The second end 282 of the bridge component 28 is connected to the inner end of the second pin 253. That is, there is a solder layer 256 cured by reflow between the inner end of the first pin 255 and the bottom contact of the die 23. Reflow-solidified solder 27′ (from the solder ball 27 shown in FIG. 2I) is located between the concave portion 283 of the first end 281 of the bridge component 28 and the electrode pad 22 of the die 23, There may also be a solder layer 254 cured by reflow between the second end 282 of the bridge component 28 and the inner end of the second pin 253. The package body 29 covers the die 23 and the bridge component 28, and covers the inner ends of the first pin 255 and the second pin 253. Outer ends of the first pin 255 and the second pin 253 are exposed or extended out of the package body 29.

In the second embodiment of the present invention, the concave portion 283 of the bridge component 28 is used to limit the position of the solder 27′ or the at least one solder ball 27. That is, the wall of the concave portion 283 by the bridge component 28 prevents the at least one solder ball 27 from flowing when melted, so as not to overflow. In addition, there are a variety of solder balls with different volume specifications on the market. Therefore, by selecting a specific specification of solder balls and their quantity, the amount of solder can be precisely controlled without excess or inadequacy, and the soldering quality can be effectively controlled.

### 3. Third Embodiment

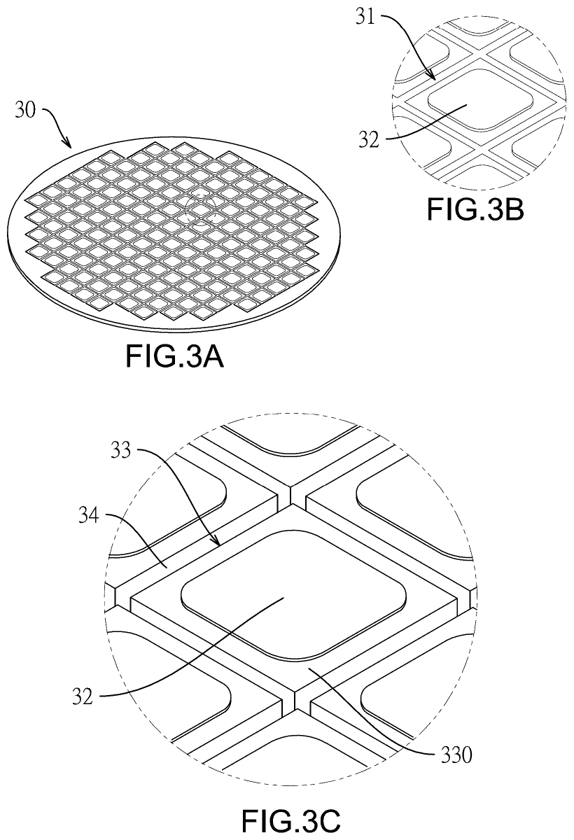

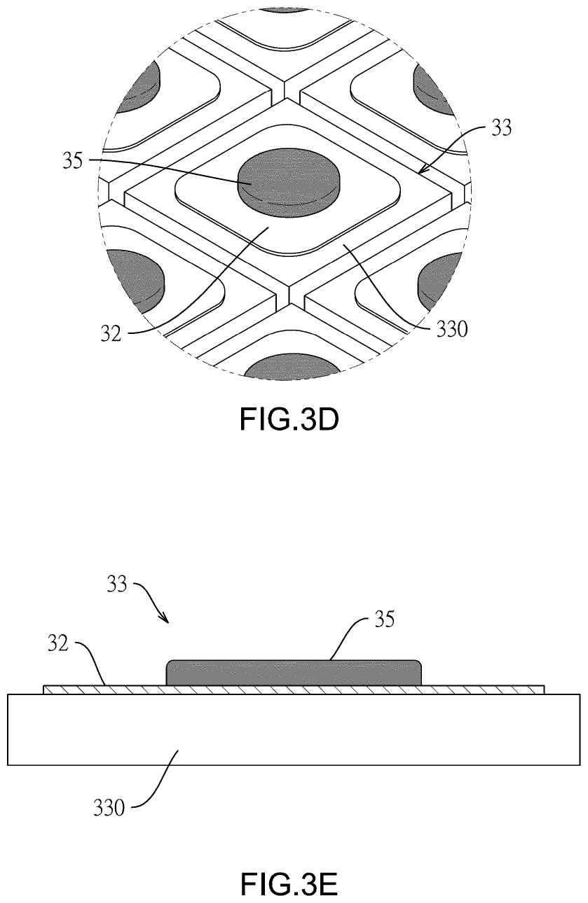

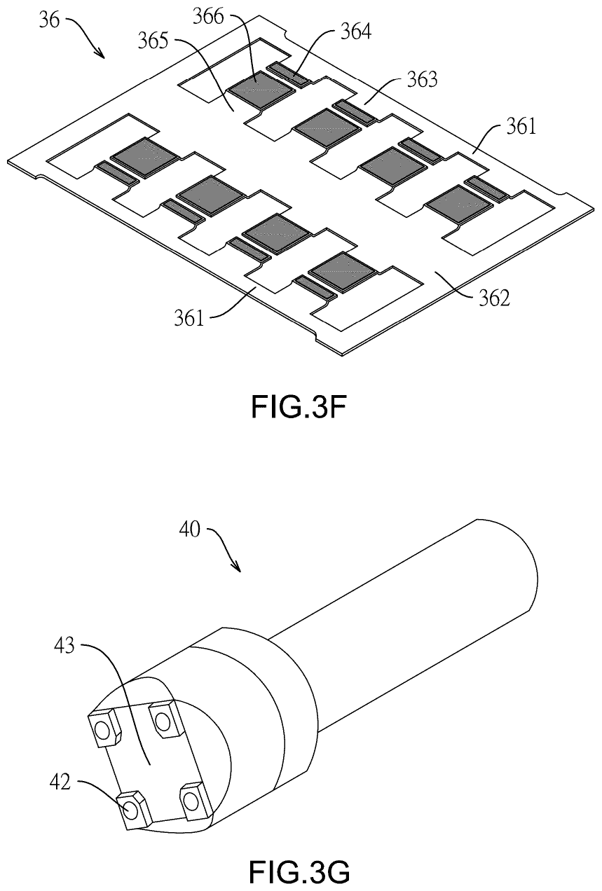

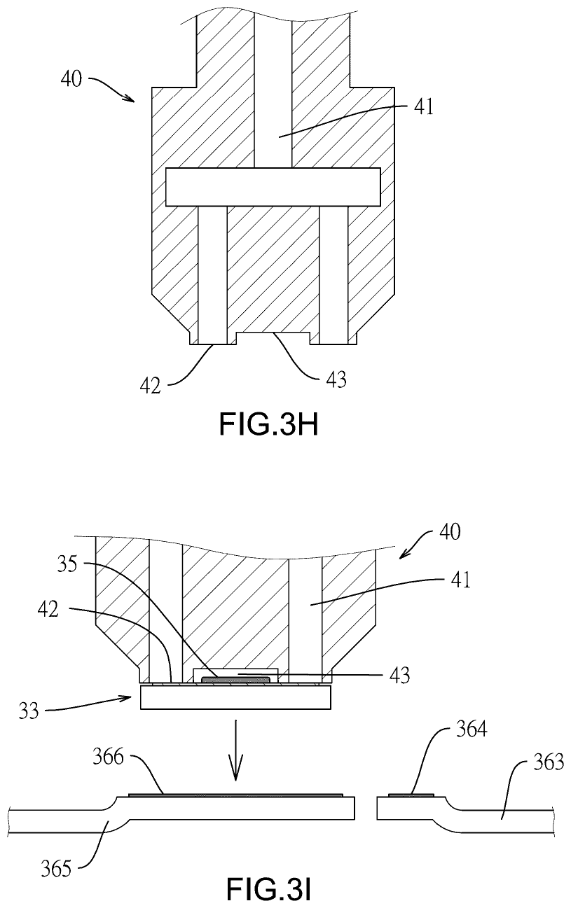

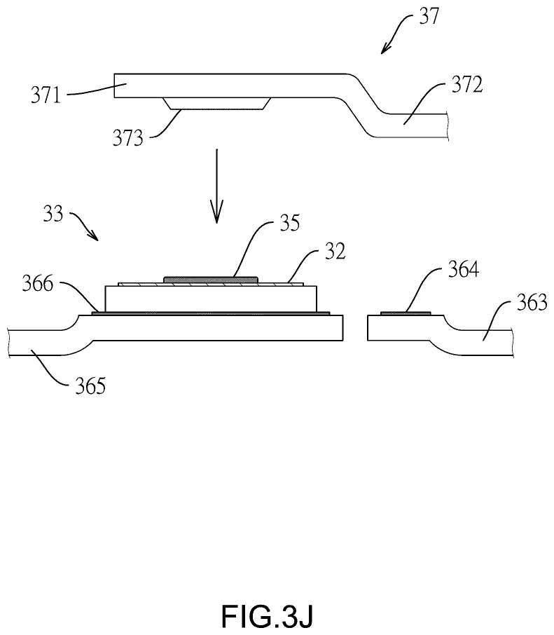

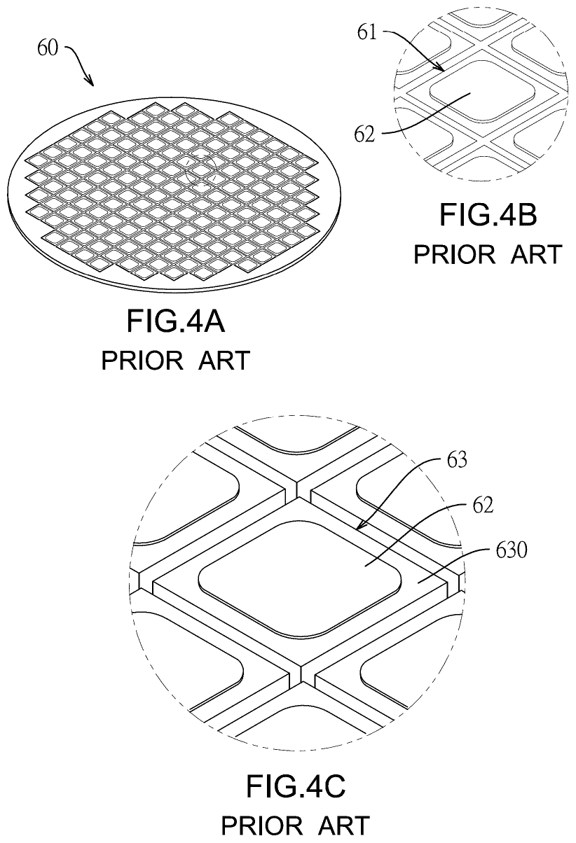

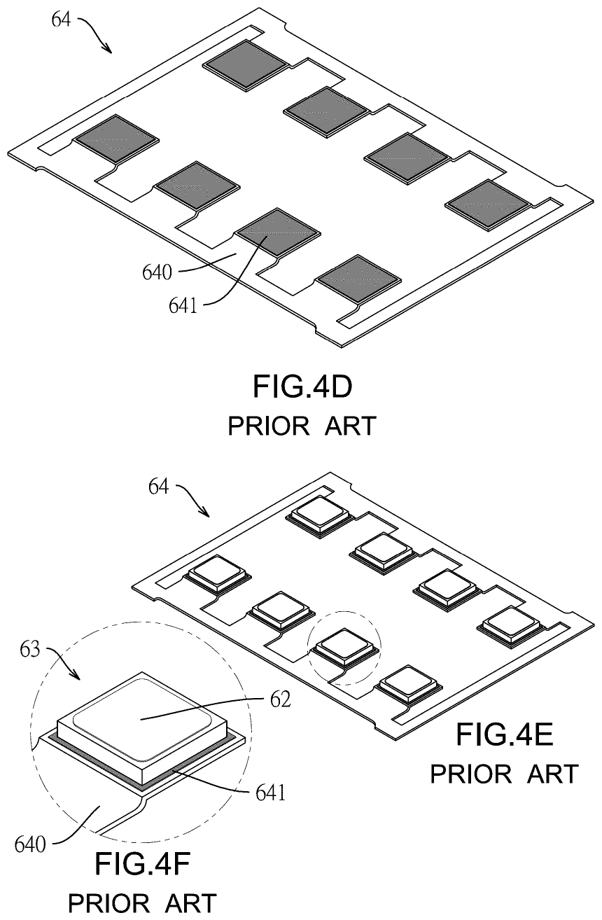

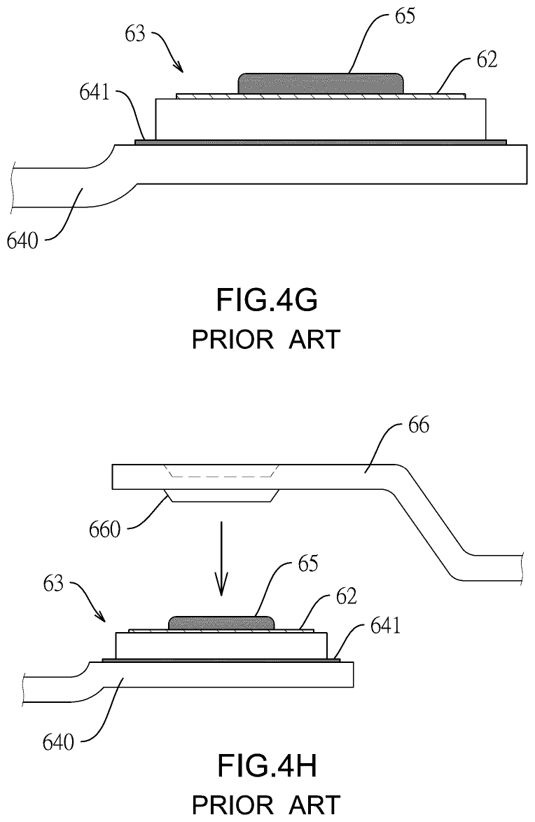

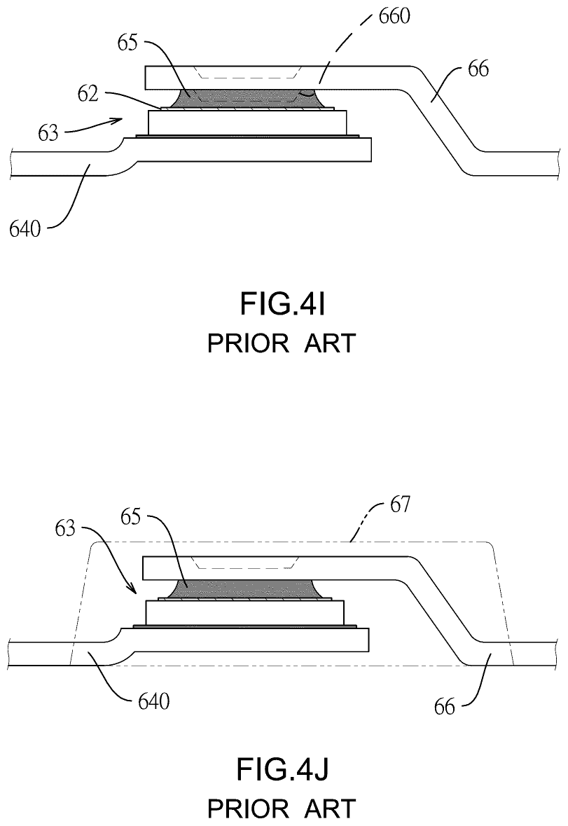

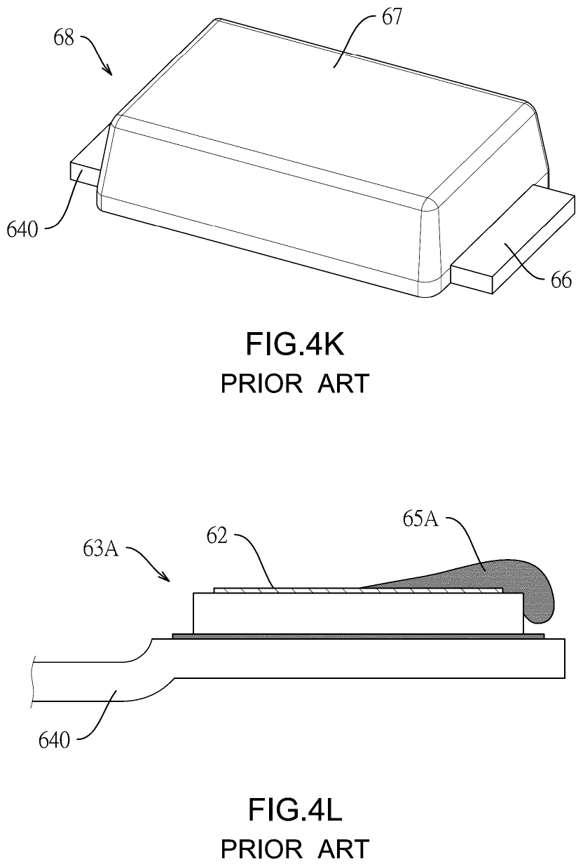

Referring to FIGS. 3A and 3B, a wafer 30 is prepared. Multiple die units 31 are formed in the wafer 30. An electrode pad 32 is formed on a top surface of each die unit 31.

Then, the wafer 30 is cut to separate the die units 31 from each other. Referring to FIG. 3C, each die unit 31 forms a single die 33, and cutting channels 34 are formed after cutting between adjacent dies 33. The die 33 includes a body 330 and the electrode pad 32 disposed on the top surface of the body 330.

Referring to FIG. 3D and FIG. 3E, a solder 35 is dispensed on the surface of the electrode pad 32 of each die 33. The solder 35 can be disposed in the center of the electrode pad 32; for example, the solder 35 can be directly disposed on the surface of the electrode pads 32 of the dies 33 by screen printing. It can be known that the positions of the multiple holes on the screen-printing plate correspond to the positions of the electrode pads 32 of the dies 33.

Referring to FIG. 3F, a first lead frame 36 is prepared. The structure of the first lead frame 36 can be referred to the first lead frame 25 of FIG. 2D of the second embodiment, which will not be repeated here. In short, the first lead frame 36 shown in FIG. 3F includes two side bars 361 and a backbone 362 between the two side bars 361. The opposite sides of the backbone 362 respectively extend outward to form multiple first pins 365. Each first pin 365 is provided with a solder layer 366. Each of the side bars 361 extends inward to form multiple second pins 363. Each second pin 363 is provided with a solder layer 364.

Referring to FIG. 3G, FIG. 3H and FIG. 3I, die bonding is performed to place the dies 33 on the solder layers 366 of the first pins 365. Wherein, in the present invention, a suction nozzle 40 sucks each of the dies 33 and moves to the solder layer 366. The suction nozzle 40 contains a gas flow channel 41. The bottom surface of the suction nozzle 40 is provided with multiple suction holes 42. The suction holes 42 communicate with the gas flow channel 41. A concave 43 is provided on the bottom surface of the suction nozzle 40 at the center of the suction holes 42. The positions of the suction holes 42 correspond to the periphery of the top surface of the die 33. When the suction holes 42 suck the periphery of the top surface of the die 33, the concave space provided by the concave 43 can prevent the solder 35 from adhering to the bottom surface of the suction nozzle 40. Therefore, when the suction nozzle 40 sucks the die 33, the suction nozzle 40 prevents the solder 35 from adhering to the solder 35.

Referring to FIG. 3J, a bridge component 37 is soldered to the electrode pad 32 of the die 33 and connected to the second pin 363. Wherein, the multiple bridge components 37 are disposed on a second lead frame (not shown in the figure). The structure of the second lead frame can be referred to the second embodiment, which will not be repeated here. Referring to FIG. 3J, each of the bridge components 37 has a first end 371 and a second end 372. The bottom surface of the first end 371 has a protruding portion 373 protruding downward. The protruding portion 373 is connected to the solder 35 on the electrode pad 32 from above the die 33. The second end 372 of the bridge component 37 is disposed on the solder layer 364 of the second pin 363. A reflow method is implemented to solder the protruding portion 373 of the bridge component 37 to the electrode pad 32 of the die 33, to solder the bottom of the die 22 to the first pin 365, and to solder the second end 372 of the bridge component 37 to the second pin 363.

Then, a molding step is performed to form a package body, which can be deduced from FIG. 1L of the first embodiment and FIG. 2J of the second embodiment, and so on, which will not be repeated. In short, the package body covers the die 33 and the bridge component 37, and partially covers the first pin 365 and the second pin 363. One end of the first pin 365 opposite to the die 33 is exposed to the package body, and one end of the second pin 363 opposite to the die 33 is exposed to the package body 29. Then, the first lead frame 36 and the second lead frame are cut to remove the package body to obtain a finished product of the package device of the present invention (see FIG. 1M for its appearance).

In the foregoing, the screen printing of FIGS. 3D and 3E can also be replaced by ball bonding. For the ball bonding, please refer to FIGS. 2F and 2G of the second embodiment. Therefore, when the die is sucked by the suction nozzle 40, the solder ball can be located in the concave 43 of the suction nozzle 40. Correspondingly, the structure of the bridge component 37 of FIG. 3J of the third embodiment can be replaced by the bridge component 28 of FIGS. 2H to 2J of the second embodiment.

In the third embodiment of the present invention, when the solder 35 is disposed at the center of the surface of the electrode pad 32 of the die 33 by means of screen printing, the amount of the solder 35 to be dispensed is precisely limited by the size and position of the holes in the screen-printing plate. When the solder balls 27 are disposed at the center of the surface of the electrode pads 32 of the die 33 by means of ball bonding, the amount of solder can be precisely controlled. And the concave portion 283 of the bridge component 28 restricts the flow of the solder ball 27 during melting. In addition, according to the structure of the suction nozzle 40, the suction nozzle 40 can suck and move the dies 33 onto the first pins 365 without being stained by the solder 35.

In summary, the present invention can provide a space or structure that can limit the position of the solder when distributing the solder on the surface of the electrode pad, such as the anti-overflow layer 13 of the first embodiment of the present invention, the structure of the at least one of solder ball 27 and the concave portion 283 of the bridge component 28, and the ball-mounting method or screen printing method in the third embodiment to set the solder, which can effectively avoid the solder overflowing during the soldering process.

What is claimed is:

1. A package device preventing solder overflow, comprising:
a die with an electrode pad;
an anti-overflow layer disposed on a top surface of the electrode pad and having an opening to expose the top surface of the electrode pad;
a first pin connected to the die;
a second pin soldered to the electrode pad of the die through the opening of the anti-overflow layer; and
a package body covering the die.

2. The package device as claimed in claim 1, wherein a size of the electrode pad is smaller than a size of the anti-overflow layer, and an edge of the electrode pad is within an edge of the anti-overflow layer.

3. The package device as claimed in claim 1, wherein a center of the anti-overflow layer has the opening.

4. The package device as claimed in claim 1, wherein the die includes a bottom contact soldered to the first pin.

5. The package device as claimed in claim 1, wherein a cured solder is formed and connected between an inner end of the second pin and the electrode pad and within the opening of the anti-overflow layer.

6. A package device preventing solder overflow, comprising:
a die with an electrode pad;
a first pin connected to the die;
a second pin opposite to the first pin at an interval;
a bridge component including:
a first end having a concave portion, wherein the concave portion is soldered to the electrode pad of the die; and
a second end connected to the second pin; and
a package body covering the die.

7. The package device as claimed in claim 6, wherein the die includes a bottom contact soldered to the first pin.

8. The package device as claimed in claim 6, wherein a reflow-solidified solder is located between the concave portion of the bridge component and the electrode pad of the die.
